(19) United States
(12) Patent Application Publication
(10) Pub. No.: US 2024/0360550 A1
(43) Pub. Date: Oct. 31, 2024

(54) C-AXIS ORIENTED IZO MATERIAL FILM AND MANUFACTURING METHOD THEREFOR

(71) Applicant: IUCF-HYU (INDUSTRY-UNIVERSITY COOPERATION FOUNDATION HANYANG UNIVERSITY), Seoul (KR)

(72) Inventors: Jin Seong PARK, Seongnam-si (KR); Tae Hyun HONG, Seoul (KR); Yoon Seo KIM, Seoul (KR)

(73) Assignee: IUCF-HYU (INDUSTRY-UNIVERSITY COOPERATION FOUNDATION HANYANG UNIVERSITY), Seoul (KR)

(21) Appl. No.: 18/768,171

(22) Filed: Jul. 10, 2024

Related U.S. Application Data
(63) Continuation of application No. PCT/KR2022/021583, filed on Dec. 29, 2022.

(30) Foreign Application Priority Data
Jan. 11, 2022 (KR) 10-2022-0003697

(51) Int. Cl. C23C 16/40; C23C 16/50; H01L 21/02

(52) U.S. Cl. CPC C23C 16/407; C23C 16/50; H01L 21/02205; H01L 21/02483; H01L 21/02565

(57) ABSTRACT

An IZO material film manufacturing method is provided. The IZO material film manufacturing method comprises the steps of: preparing a substrate; reacting a first precursor, which comprises indium (In), and a first reactant, which comprises plasma, thereby forming, on the substrate, a first material film comprising indium oxide; and reacting a second precursor, which comprises zinc (Zn), and a second reactant, which comprises plasma, thereby forming, on the first material film, a second material film comprising zinc oxide, and may comprise performing, multiple times, each of the step of forming the first material film and the step of forming the second material film, and controlling the proportion of the number of repetitions of the step of forming the second material film to the number of repetitions of the step of forming the first material film, thereby controlling the crystal growth of an IZO material film in which the first material film and the second material film are stacked.

### TECHNICAL FIELD

The present invention relates to a C-axis oriented IZO material film and a manufacturing method therefor, and more particularly, to a C-axis oriented IZO material film that may be applied to various semiconductor devices, and a manufacturing method therefor.

### BACKGROUND ART

In the existing display market, an a-InGaZnO material is attracting attention in the field of transistor researches in response to market demands for application of flexible displays and high-resolution OLEDs using low-temperature processes, and there are actual application cases of the a-InGaZnO material. Currently, there are research cases aimed at using excellent off-current advantages of oxide semiconductors in the memory semiconductor industry. As the scope of researches expands, researches for application to high-temperature processes without being limited to low-temperature processes in terms of process temperatures are being conducted.

In particular, the low-temperature processes of the oxide semiconductors may be applied to flexible substrates such as PI and PEN substrates without being limited to rigid substrates, so that applicability and value of next-generation displays (flexible and stretchable displays) are being increased. The existing commercialized deposition scheme for the oxide semiconductors is PVD (sputtering), which is used for advantages of a fast deposition speed and high reproducibility, whereas the PVD has limitations in applying 3D materials that require a high aspect ratio due to disadvantages of difficulties in controlling a metal composition ratio of the oxide semiconductor, low step coverage, and the like. Accordingly, researches on oxide semiconductors using an ALD deposition scheme capable of depositing a thin film having high step coverage, having a composition ratio that is easily controlled, and having a high film density are increasing recently. A thermal ALD-based IZO material is one of the materials that have been previously studied, but it has been reported that amorphous thin film characteristics appear mostly, since heterogeneous crystal phases of InO (cubic structure—coordination number: 6) thin films and ZnO (Hexagonal structure—coordination number: 4) are mixed.

Silicon-based semiconductors have a small band gap so as to be opaque so that it is difficult to apply the silicon-based semiconductors in development of transparent materials, when the semiconductor is amorphous, large-area processes may be performed at low temperatures, while charge mobility is limited to ˜1 cm²/Vs, and when the semiconductor is polycrystalline, mobility is high, while there are clear limitations due to required high-temperature processes and a uniformity issue, which is disadvantageous to large-area processes. For this reason, many researches on oxide semiconductor-based transistors have been conducted, and sputtering-based a-IGZO materials have begun to be applied to backplane transistors in the display field. However, it is difficult to control composition ratios and nm-scale thicknesses, and there are limitations in implementing 3D structures, so that many researches on ALD-based oxide semiconductors have been conducted recently. Researches on various material groups such as ALD-InO, ALD-IGZO, and ALD-IGO have been reported. In terms of reproducing characteristics of oxide semiconductors, it is industrially advantageous to reduce types of metal elements (e.g., IGZO→three metal elements of In, Ga, and Zn). Accordingly, IZO researches excluding gallium (Ga) have been previously reported, in which possibility of exhibiting characteristics of high mobility have been reported. However, due to absence of gallium (Ga) that has a stable bond with oxygen, there are limitations in implementing reliability and stable device characteristics. Accordingly, researches on ALD-based oxide semiconductors capable of implementing high reliability and stable device characteristics without gallium (Ga) are continuously being conducted.

### DISCLOSURE

### Technical Problem

One technical object of the present invention is to provide an oxide-based semiconductor thin film in which gallium (Ga) is omitted, and a manufacturing method therefor.

Another technical object of the present invention is to provide an IZO material film and a manufacturing method therefor, capable of controlling crystal growth through control of process variables.

Still another technical object of the present invention is to provide an IZO material film and a manufacturing method therefor, capable of controlling electrical characteristics through control of process variables.

Yet another technical object of the present invention is to provide an IZO material film having a C-axis crystal phase, and a manufacturing method therefor.

Technical objects of the present invention are not limited to the technical objects described above.

### Technical Solution

To achieve the technical objects described above, the present invention provides a method for manufacturing an IZO material film.

According to one embodiment, the method for manufacturing the IZO material film includes: preparing a substrate; forming a first material film including indium oxide on the substrate by reacting a first precursor including indium (In) with a first reactant including plasma; and forming a second material film including zinc oxide on the first material film by reacting a second precursor including zinc (Zn) with a second reactant including plasma, wherein each of the forming of the first material film and the forming of the second material film is repeatedly performed a plurality of times, and a ratio of a number of repetitions of the forming of the second material film to a number of repetitions of the forming of the first material film is controlled to control crystal growth of an IZO material film in which the first material film and the second material film are stacked.

According to one embodiment, the ratio of the number of repetitions of the forming of the second material film to the number of repetitions of the forming of the first material film may be controlled to be greater than 6:1 and less than 1:3, so that the IZO material film may be subjected to C-axis oriented crystal growth.

According to one embodiment, the ratio of the number of repetitions of the forming of the second material film to the number of repetitions of the forming of the first material film may be controlled to be greater than or equal to 1:3 and less than or equal to 1:6, so that the IZO material film may be subjected to polycrystalline crystal growth.

According to one embodiment, the ratio of the number of repetitions of the forming of the second material film to the number of repetitions of the forming of the first material film may be controlled to be greater than or equal to 12:1 and less than or equal to 6:1, so that the IZO material film may be subjected to amorphous crystal growth.

According to one embodiment, the ratio of the number of repetitions of the forming of the second material film to the number of repetitions of the forming of the first material film may be controlled to be greater than or equal to 36:1 and less than or equal to 18:1, so that the IZO material film may be subjected to polycrystalline crystal growth.

According to one embodiment, the first material film may exhibit a cubic-InOₓ crystal phase (x>0) as a result of X-ray diffraction (XRD) analysis.

According to one embodiment, the second material film may exhibit a hexagonal-ZnO crystal phase as a result of X-ray diffraction (XRD) analysis.

According to one embodiment, the first precursor may be represented by <Chemical Formula 1> below.

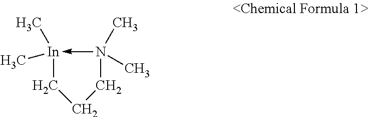

According to one embodiment, the second precursor may be represented by <Chemical Formula 2> below.

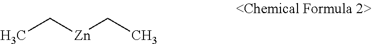

To achieve the technical objects described above, the present invention provides an IZO material film.

According to one embodiment, there is provided the IZO material film, wherein, in an InₓZn_{y}O material film (x,y>0) in which a first material film including indium oxide and a second material film including zinc oxide are stacked, a composition of indium (In) and zinc (Zn) in the InₓZn_{y}O material film (x,y>0) is controlled to control a crystal phase of the InₓZn_{y}O material film (x,y>0).

According to one embodiment, x may be controlled to be greater than 0.11 and less than 0.44, and y may be controlled to be greater than 0.56 and less than 0.89, so that the InₓZn_{y}O material film may have a C-axis crystal phase.

According to one embodiment, x may be controlled to be greater than or equal to 0.07 and less than or equal to 0.11, and y may be controlled to be greater than or equal to 0.89 and less than or equal to 0.93, so that the InₓZn_{y}O material film may have a hexagonal-ZnO crystal phase.

According to one embodiment, x may be controlled to be greater than or equal to 0.44 and less than or equal to 0.60, and y may be controlled to be greater than or equal to 0.40 and less than or equal to 0.56, so that the InₓZn_{y}O material film may have an amorphous crystal phase.

According to one embodiment, x may be controlled to be greater than or equal to 0.62 and less than or equal to 0.68, and y may be controlled to be greater than or equal to 0.32 and less than or equal to 0.38, so that the InₓZn_{y}O material film may have a cubic-InO crystal phase.

### Advantageous Effects

According to an embodiment of the present invention, a method for manufacturing an IZO material film may include: preparing a substrate; forming a first material film including indium oxide on the substrate by reacting a first precursor including indium (In) with a first reactant including plasma; and forming a second material film including zinc oxide on the first material film by reacting a second precursor including zinc (Zn) with a second reactant including plasma, wherein each of the forming of the first material film and the forming of the second material film is repeatedly performed a plurality of times, and a ratio of a number of repetitions of the forming of the second material film to a number of repetitions of the forming of the first material film is controlled to control crystal growth of an IZO material film in which the first material film and the second material film are stacked.

In particular, the ratio of the number of repetitions of the forming of the second material film to the number of repetitions of the forming of the first material film may be controlled to be greater than 6:1 and less than 1:3 (InₓZn_{y}O, x: greater than 0.11 and less than 0.44, y: greater than 0.56 and less than 0.89), so that the IZO material film may have a C-axis crystal phase. The IZO material film having the C-axis crystal phase can have a high film density and a stable metal-oxygen bond (M-O bond). Accordingly, a transistor to which the IZO material film having the C-axis crystal phase is applied can have improved electrical characteristics.

### DESCRIPTION OF DRAWINGS

FIG. 1 is a flowchart for describing a method for manufacturing an IZO material film according to an embodiment of the present invention.

FIGS. 2 and 3 are views for describing processes of manufacturing the IZO material film according to the embodiment of the present invention.

FIGS. 4 and 5 are views for describing variations in composition of the IZO material film according to process variables according to the embodiment of the present invention.

FIG. 6 is a view for describing an XRD result of an In₂O₃ material film formed during the process of manufacturing the IZO material film according to Experimental Example 3 of the present invention.

FIG. 7 is a view for describing an XRD result of a ZnO material film formed during the process of manufacturing the IZO material film according to Experimental Example 3 of the present invention.

FIG. 8 is a view for describing XRD results of IZO material films according to experimental examples of the present invention.

FIG. 9 is a view for describing XPS results of the IZO material films for O is according to the experimental examples of the present invention.

FIGS. 10 and 11 are views for describing calculated film densities and measured film densities of IZO thin films according to embodiments of the present invention.

FIG. 12 is a view for specifically describing an IZO material film according to Experimental Example 2 of the present invention.

FIG. 13 is a view for specifically describing an IZO material film according to Experimental Example 3 of the present invention.

FIG. 14 is a view for specifically describing an IZO material film according to Experimental Example 4 of the present invention.

FIG. 15 is a view for specifically describing an IZO material film according to Experimental Example 8 of the present invention.

FIG. 16 is a view for describing XRD analysis results of IZO material films according to comparative examples of the present invention.

FIG. 17 is a view for describing a transistor according to the experimental example of the present invention.

FIG. 18 is a view for describing electrical characteristics of a transistor according to Experimental Example 3 of the present invention.

FIG. 19 is a view for comparing electrical characteristics of transistors according to the experimental examples of the present invention.

### MODE FOR INVENTION

Hereinafter, exemplary embodiments of the present invention will be described in detail with reference to the accompanying drawings. However, the technical idea of the present invention is not limited to the embodiments described herein, but may be embodied in different forms. The embodiments introduced herein are provided to sufficiently deliver the idea of the present invention to those skilled in the art so that the disclosed contents may become thorough and complete.

When it is mentioned in the present disclosure that one element is on another element, it means that one element may be directly formed on another element, or a third element may be interposed between one element and another element. Further, in the drawings, thicknesses of films and regions are exaggerated for effective description of the technical contents.

In addition, although the terms such as first, second, and third have been used to describe various elements in various embodiments of the present disclosure, the elements are not limited by the terms. The terms are used only to distinguish one element from another element. Therefore, an element mentioned as a first element in one embodiment may be mentioned as a second element in another embodiment. The embodiments described and illustrated herein include their complementary embodiments, respectively. Further, the term “and/or” used in the present disclosure is used to include at least one of the elements enumerated before and after the term.

As used herein, an expression in a singular form includes a meaning of a plural form unless the context clearly indicates otherwise. Further, the terms such as “including” and “having” are intended to designate the presence of features, numbers, steps, elements, or combinations thereof described herein, and shall not be construed to preclude any possibility of the presence or addition of one or more other features, numbers, steps, elements, or combinations thereof. In addition, the term “connection” used herein is used to include both indirect and direct connections of a plurality of elements.

Further, in the following description of the present invention, detailed descriptions of known functions or configurations incorporated herein will be omitted when they may make the gist of the present invention unnecessarily unclear.

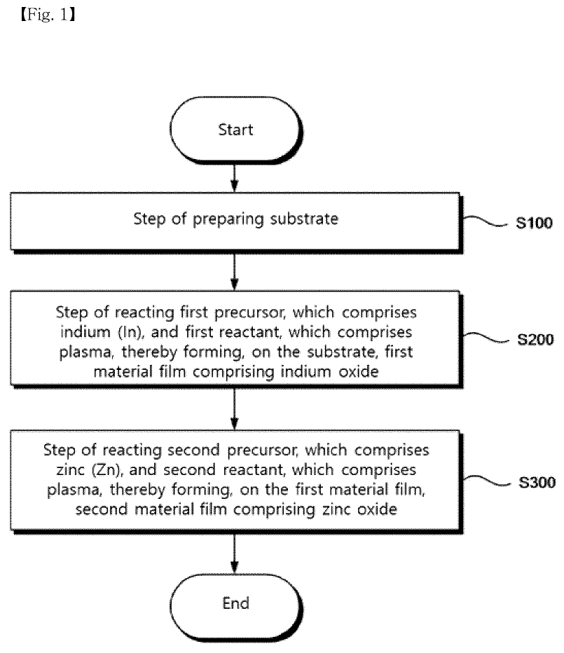

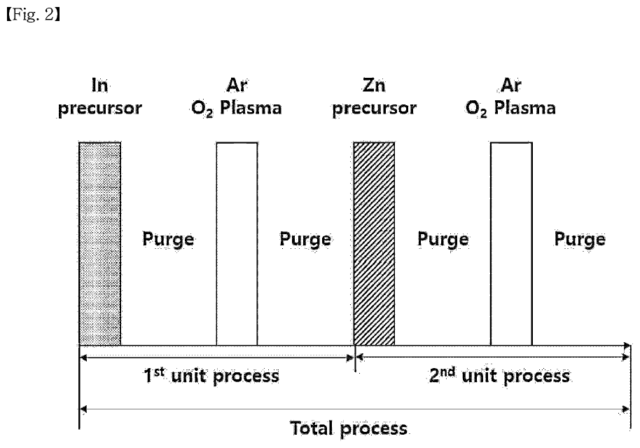

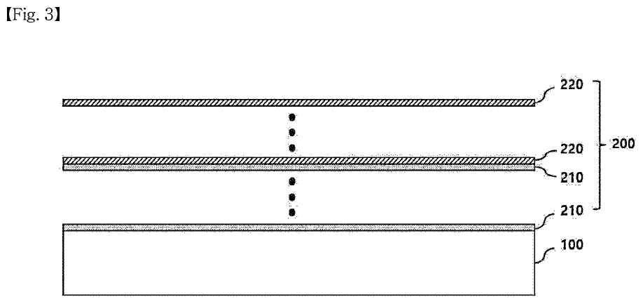

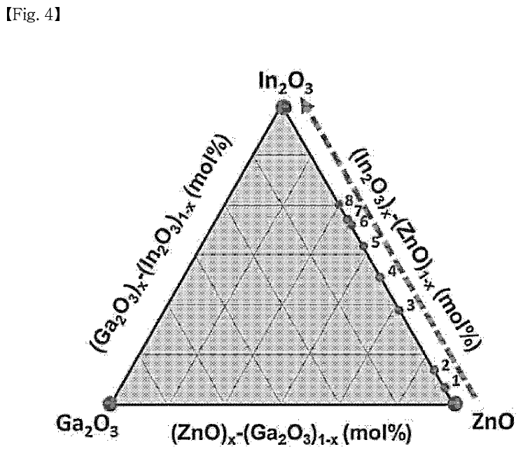

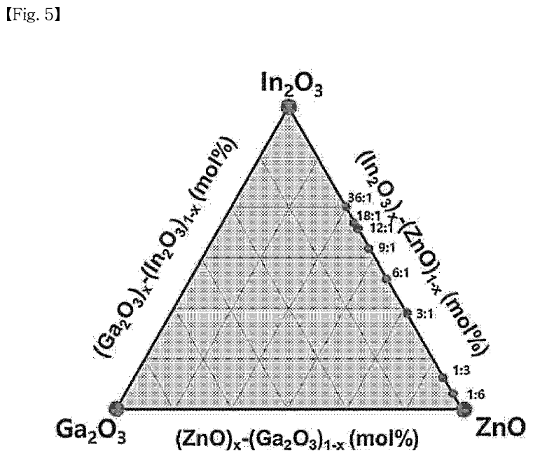

FIG. 1 is a flowchart for describing a method for manufacturing an IZO material film according to an embodiment of the present invention, FIGS. 2 and 3 are views for describing processes of manufacturing the IZO material film according to the embodiment of the present invention, and FIGS. 4 and 5 are views for describing variations in composition of the IZO material film according to process variables according to the embodiment of the present invention.

Referring to FIGS. 1 to 3, a substrate 100 may be prepared (S100). According to one embodiment, the substrate 100 may be a silicon semiconductor substrate. Alternatively, according to another embodiment, the substrate 100 may be one of a compound semiconductor substrate, a glass substrate, or a plastic substrate. A type of the substrate 100 is not limited.

A first precursor including indium (In) and a first reactant including plasma may be provided on the substrate 100 to form a first material film 210 obtained by reacting the first precursor with the first reactant (S200). Accordingly, the first material film 210 may include indium oxide. For example, the first material film 210 may include In₂O₃.

According to one embodiment, the first material film 210 may be formed by a plasma-enhanced atomic layer deposition (PEALD) process. The first material film 210 formed by the PEALD process may have a cubic-InOₓ crystal phase (x>0) as a result of X-ray diffraction (XRD) analysis.

In more detail, the forming of the first material film 210 may include: providing the first precursor on the substrate 100; performing purge; providing the first reactant on the substrate 100 on which the first precursor is provided; and performing purge. For example, the first precursor may be represented by <Chemical Formula 1> below. For example, the first reactant may include oxygen plasma (O₂). In addition, the first reactant may further include argon (Ar).

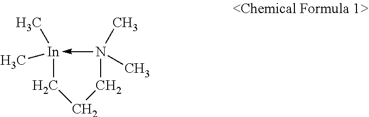

The providing of the first precursor—the performing of the purge—the providing of the first reactant—the performing of the purge may be defined as a first unit process (1^{st} unit process). The first unit process may be repeatedly performed a plurality of times. Accordingly, a thickness of the first material film 210 may be controlled.

A second precursor including zinc (Zn) and a second reactant including plasma may be provided on the first material film 210 to form a second material film 220 obtained by reacting the second precursor with the second reactant (S300). Accordingly, the second material film 220 may include zinc oxide. For example, the second material film 220 may include ZnO.

According to one embodiment, the second material film 220 may be formed by a plasma-enhanced atomic layer deposition (PEALD) process. The second material film 220 formed by the PEALD process may have a hexagonal-ZnO crystal phase as a result of X-ray diffraction (XRD) analysis.

In more detail, the forming of the second material film 220 may include: providing the second precursor on the first material film 210; performing purge; providing the second reactant on the first material film 210 on which the second precursor is provided; and performing purge. For example, the second precursor may be represented by <Chemical Formula 2> below. For example, the second reactant may include oxygen plasma (O₂). In addition, the second reactant may further include argon (Ar).

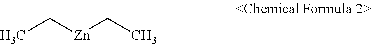

The providing of the second precursor—the performing of the purge—the providing of the second reactant—the performing of the purge may be defined as a second unit process (2^{nd} unit process). The second unit process may be repeatedly performed a plurality of times. Accordingly, a thickness of the second material film 220 may be controlled.

Since the first material film 210 and the second material film 220 are formed, an InₓZn_{y}O material film 200 (x,y>0) in which the first material film 210 and the second material film 220 are stacked may be formed. The InₓZn_{y}O material film (x,y>0) may be defined as an IZO material film. In other words, the IZO material film 200 may be formed on the substrate 100 by the PEALD process.

According to one embodiment, the first unit process—the second unit process may be defined as a total process (Total process). The total process may be repeatedly performed a plurality of times. Accordingly, a thickness of the IZO material film 200 may be controlled.

A ratio of the number of repetitions of the forming of the second material film 220 to the number of repetitions of the forming of the first material film 210 may be controlled to control crystal growth of the IZO material film 200. In other words, the number of repetitions of the second unit process with respect to the number of repetitions of the first unit process may be controlled to control the crystal growth of the IZO material film 200.

In detail, when the ratio of the number of repetitions of the forming of the second material film to the number of repetitions of the forming of the first material film 210 is controlled to be greater than or equal to 1:3 and less than or equal to 1:6 (point 1 and point 2 in FIG. 4), the IZO material film 200 may be subjected to polycrystalline crystal growth. The IZO material film 200 formed under a condition that the ratio of the number of repetitions of the forming of the second material film to the number of repetitions of the forming of the first material film 210 is greater than or equal to 1:3 and less than or equal to 1:6 may have a composition of InₓZn_{y}O (x: greater than or equal to 0.07 and less than or equal to 0.11, y: greater than or equal to 0.89 and less than or equal to 0.93), and may have a hexagonal-ZnO crystal phase.

Alternatively, when the ratio of the number of repetitions of the forming of the second material film to the number of repetitions of the forming of the first material film 210 is controlled to be greater than 6:1 and less than 1:3 (point 3 in FIG. 4), the IZO material film 200 may be subjected to C-axis oriented crystal growth. The IZO material film 200 formed under a condition that the ratio of the number of repetitions of the forming of the second material film to the number of repetitions of the forming of the first material film 210 is greater than 6:1 and less than 1:3 may have a composition of InₓZn_{y}O (x: greater than 0.11 and less than 0.44, y: greater than 0.56 and less than 0.89), and may have a C-axis crystal phase.

Alternatively, when the ratio of the number of repetitions of the forming of the second material film to the number of repetitions of the forming of the first material film 210 is controlled to be greater than or equal to 12:1 and less than or equal to 6:1 (point 4, point 5, and point 6 in FIG. 4), the IZO material film 200 may be subjected to amorphous crystal growth. The IZO material film 200 formed under a condition that the ratio of the number of repetitions of the forming of the second material film to the number of repetitions of the forming of the first material film 210 is greater than or equal to 12:1 and less than or equal to 6:1 may have a composition of InₓZn_{y}O (x: greater than or equal to 0.44 and less than or equal to 0.60, y: greater than or equal to 0.40 and less than or equal to 0.56), and may have an amorphous crystal phase.

Alternatively, when the ratio of the number of repetitions of the forming of the second material film to the number of repetitions of the forming of the first material film 210 is controlled to be greater than or equal to 36:1 and less than or equal to 18:1 (point 7 and point 8 in FIG. 4), the IZO material film 200 may be subjected to polycrystalline crystal growth. The IZO material film 200 formed under a condition that the ratio of the number of repetitions of the forming of the second material film to the number of repetitions of the forming of the first material film 210 is greater than or equal to 36:1 and less than or equal to 18:1 may have a composition of InₓZn_{y}O (x: greater than or equal to 0.62 and less than or equal to 0.68, y: greater than or equal to 0.32 and less than or equal to 0.38), and may have a cubic-InO crystal phase.

As a result, according to an embodiment of the present invention, a method for manufacturing an IZO material film may include: preparing a substrate; forming a first material film including indium oxide on the substrate by reacting a first precursor including indium (In) with a first reactant including plasma; and forming a second material film including zinc oxide on the first material film by reacting a second precursor including zinc (Zn) with a second reactant including plasma, wherein each of the forming of the first material film and the forming of the second material film is repeatedly performed a plurality of times, and a ratio of a number of repetitions of the forming of the second material film to a number of repetitions of the forming of the first material film is controlled to control crystal growth of an IZO material film in which the first material film and the second material film are stacked.

In particular, the ratio of the number of repetitions of the forming of the second material film to the number of repetitions of the forming of the first material film may be controlled to be greater than 6:1 and less than 1:3 (InₓZn_{y}O, x: greater than 0.11 and less than 0.44, y: greater than 0.56 and less than 0.89), so that the IZO material film may have a C-axis crystal phase. The IZO material film having the C-axis crystal phase may have a high film density and a stable metal-oxygen bond (M-O bond). Accordingly, a transistor to which the IZO material film having the C-axis crystal phase is applied may have improved electrical characteristics.

Accordingly, the IZO material film and the manufacturing method therefor according to the embodiment of the present invention have been described. Hereinafter, specific experimental examples and characteristic evaluation results of the IZO material film and the manufacturing method therefor according to the embodiment of the present invention will be described.

### Manufacture of IZO Material Film According to Experimental Example 1

An In₂O₃ material film was formed by performing a first unit process including indium precursor provision—purge—Ar/O₂ plasma provision—purge was performed on a substrate, and a ZnO material film was formed by performing a second unit process including zinc precursor provision—purge—Ar/O₂ plasma provision—purge on the In₂O₃ material film, so that an IZO material film according to Experimental Example 1 was manufactured. In more detail, the number of repetitions of the second unit process with respect to the number of repetitions of the first unit process was 1:6, and the manufactured IZO material film had a composition of In_{0.07}Zn_{0.93}O.

### Manufacture of IZO Material Film According to Experimental Example 2

An IZO material film according to Experimental Example 1 described above was manufactured, while the number of repetitions of the second unit process with respect to the number of repetitions of the first unit process was 1:3. The manufactured IZO material film had a composition of In_{0.11}Zn_{0.89}O.

### Manufacture of IZO Material Film According to Experimental Example 3

An IZO material film according to Experimental Example 1 described above was manufactured, while the number of repetitions of the second unit process with respect to the number of repetitions of the first unit process was 3:1. The manufactured IZO material film had a composition of In_{0.32}Zn_{0.68}O.

### Manufacture of IZO Material Film According to Experimental Example 4

An IZO material film according to Experimental Example 1 described above was manufactured, while the number of repetitions of the second unit process with respect to the number of repetitions of the first unit process was 6:1. The manufactured IZO material film had a composition of In_{0.44}Zn_{0.56}O.

Manufacture of IZO Material Film according to Experimental Example 5

An IZO material film according to Experimental Example 1 described above was manufactured, while the number of repetitions of the second unit process with respect to the number of repetitions of the first unit process was 9:1. The manufactured IZO material film had a composition of In_{0.52}Zn_{0.48}O.

Manufacture of IZO Material Film according to Experimental Example 6

An IZO material film according to Experimental Example 1 described above was manufactured, while the number of repetitions of the second unit process with respect to the number of repetitions of the first unit process was 12:1. The manufactured IZO material film had a composition of In_{0.60}Zn_{0.40}O.

Manufacture of IZO Material Film according to Experimental Example 7

An IZO material film according to Experimental Example 1 described above was manufactured, while the number of repetitions of the second unit process with respect to the number of repetitions of the first unit process was 18:1. The manufactured IZO material film had a composition of In_{0.62}Zn_{0.38}O.

### Manufacture of IZO Material Film According to Experimental Example 8

An IZO material film according to Experimental Example 1 described above was manufactured, while the number of repetitions of the second unit process with respect to the number of repetitions of the first unit process was 36:1. The manufactured IZO material film had a composition of In_{0.68}Zn_{0.32}O.

The numbers of repetitions of the second unit process with respect to the numbers of repetitions of the first unit process and the compositions of the IZO material films, which are controlled during processes of manufacturing the IZO material films according to Experimental Examples 1 to 8, will be summarized through <Table 1> below.

TABLE 1

| | First unit process:Second | InₓZn_{y}O |
|---|---|---|
| Classification | unit process | composition |
| Experimental Example 1 | 1:6 | In_{0.07}Zn_{0.93}O |
| Experimental Example 2 | 1:3 | In_{0.11}Zn_{0.89}O |
| Experimental Example 3 | 3:1 | In_{0.32}Zn_{0.68}O |
| Experimental Example 4 | 6:1 | In_{0.44}Zn_{0.56}O |
| Experimental Example 5 | 9:1 | In_{0.52}Zn_{0.48}O |
| Experimental Example 6 | 12:1 | In_{0.60}Zn_{0.40}O |
| Experimental Example 7 | 18:1 | In_{0.62}Zn_{0.38}O |
| Experimental Example 8 | 36:1 | In_{0.68}Zn_{0.32}O |

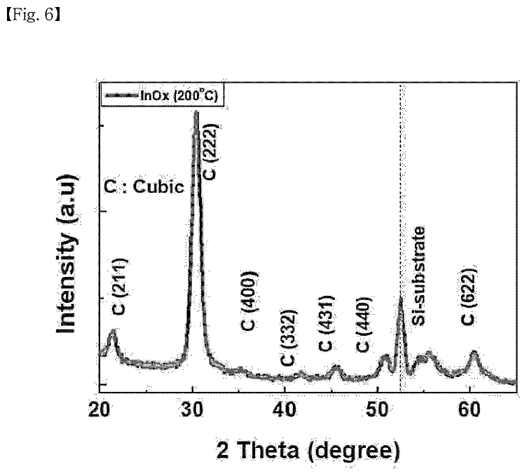

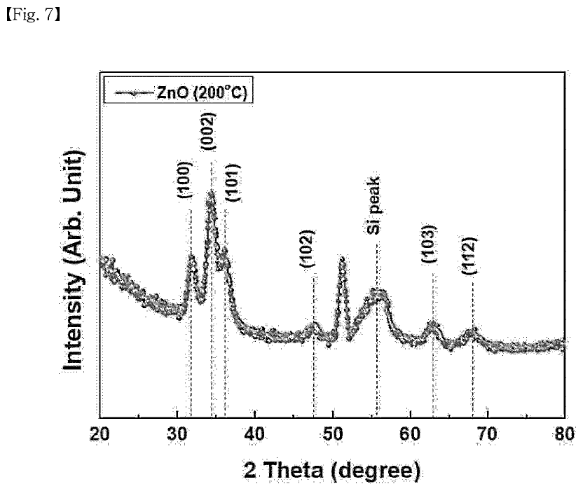

FIG. 6 is a view for describing an XRD result of an In₂O₃ material film formed during the process of manufacturing the IZO material film according to Experimental Example 3 of the present invention, and FIG. 7 is a view for describing an XRD result of a ZnO material film formed during the process of manufacturing the IZO material film according to Experimental Example 3 of the present invention. Referring to FIG. 6, an X-ray diffraction (XRD) analysis result of the In₂O₃ (InOₓ) material film formed during the process of manufacturing the IZO material film according to Experimental Example 3 is shown. As shown in FIG. 6, the In₂O₃ (InOₓ) material film exhibited a cubic-InOₓ crystal phase, and exhibited crystal growth with a strong C—InOₓ (222) orientation.

Referring to FIG. 7, an X-ray diffraction (XRD) analysis result of the ZnO material film formed during the process of manufacturing the IZO material film according to Experimental Example 3 is shown. As shown in FIG. 7, the ZnO material film exhibited a hexagonal-ZnO crystal phase, and exhibited crystal growth with a strong ZnO (002) orientation.

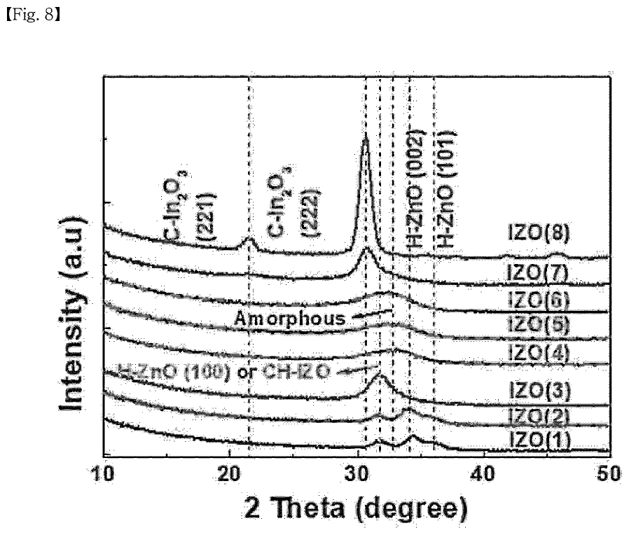

FIG. 8 is a view for describing XRD results of IZO material films according to experimental examples of the present invention.

Referring to FIG. 8, after the IZO material film according to Experimental Example 1 (IZO (1)), the IZO material film according to Experimental Example 2 (IZO (2)), the IZO material film according to Experimental Example 3 (IZO (3)), the IZO material film according to Experimental Example 4 (IZO (4)), the IZO material film according to Experimental Example 5 (IZO (5)), the IZO material film according to Experimental Example 6 (IZO (6)), the IZO material film according to Experimental Example 7 (IZO (7)), and the IZO material film according to Experimental Example 8 (IZO (8)) are prepared, X-ray diffraction (XRD) analysis was performed on each of the IZO material films.

As shown in FIG. 8, the IZO material films according to Experimental Examples 1 and 2 exhibited a hexagonal structure of a ZnO structure due to a relatively high ZnO content. In contrast, the IZO material film according to Experimental Example 3 exhibited a C-axis structure based on the hexagonal structure of the ZnO structure. In contrast, the IZO material films according to Experimental Examples 4 to 6 had a mixed structure, in which crystal phases of an InO thin film with a coordination number of 6 and a ZnO thin film with a coordination number of 4 compete with each other to exhibit amorphous characteristics. In contrast, the IZO material films according to Experimental Examples 7 and 8 exhibited a cubic structure, which is an InO structure, due to a dominant InO composition.

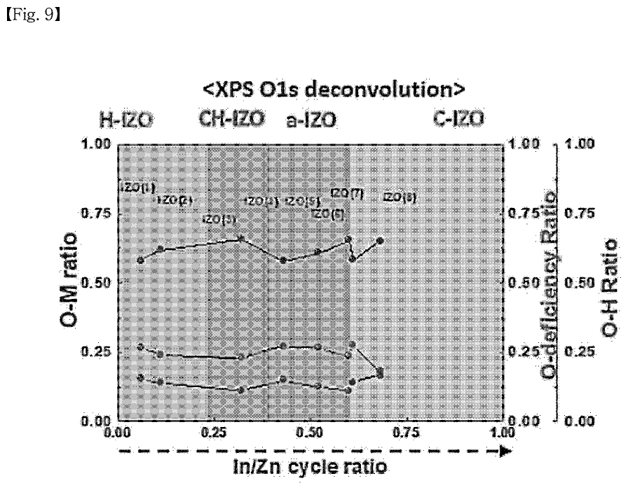

FIG. 9 is a view for describing XPS results of the IZO material films for 0 is according to the experimental examples of the present invention.

Referring to FIG. 9, after the IZO material film according to Experimental Example 1 (IZO (1)), the IZO material film according to Experimental Example 2 (IZO (2)), the IZO material film according to Experimental Example 3 (IZO (3)), the IZO material film according to Experimental Example 4 (IZO (4)), the IZO material film according to Experimental Example 5 (IZO (5)), the IZO material film according to Experimental Example 6 (IZO (6)), the IZO material film according to Experimental Example 7 (IZO (7)), and the IZO material film according to Experimental Example 8 (IZO (8)) are prepared, X-ray photoelectron spectroscopy (XPS) 0 is analysis was performed on each of the IZO material films.

As shown in FIG. 9, according to In—O dissociation energy (346 KJ/mol) and Zn—O dissociation energy (<250 KJ/mol), ZnO had a relatively unstable bond with oxygen, so that, as an In ratio increases, an M-O bond ratio was gradually increased, and an O-deficiency was gradually decreased. However, inverted characteristics were exhibited in Experimental Examples 3 and 4 (C-axis→amorphous) and Experimental Examples 6 and 7 (amorphous→cubic), which are changed. Accordingly, the IZO thin film according to Experimental Example 3 having the C-axis crystal phase had a stable M-O bond as compared with the IZO thin film according to Experimental Example 4 having the amorphous crystal phase.

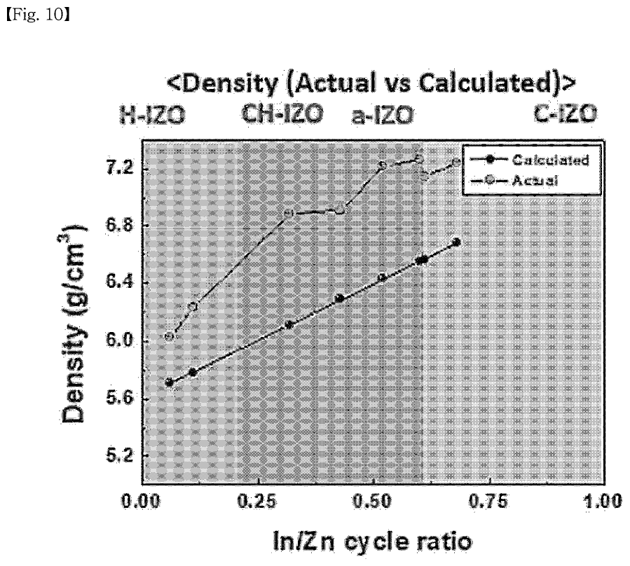

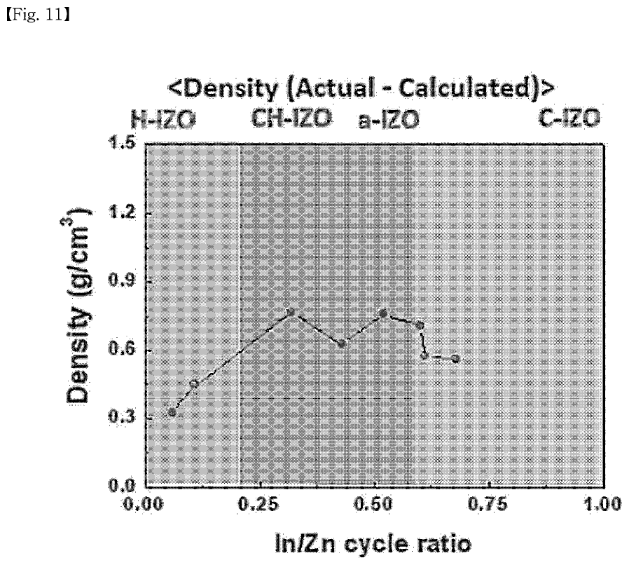

FIGS. 10 and 11 are views for describing calculated film densities and measured film densities of IZO thin films according to embodiments of the present invention.

Referring to FIGS. 10 and 11, after the IZO material film according to Experimental Example 1 (IZO (1)), the IZO material film according to Experimental Example 2 (IZO (2)), the IZO material film according to Experimental Example 3 (IZO (3)), the IZO material film according to Experimental Example 4 (IZO (4)), the IZO material film according to Experimental Example 5 (IZO (5)), the IZO material film according to Experimental Example 6 (IZO (6)), the IZO material film according to Experimental Example 7 (IZO (7)), and the IZO material film according to Experimental Example 8 (IZO (8)) are prepared, X-ray reflectometry (XRR) analysis and simulation were performed on each of the material films to measure a density of a thin film.

FIG. 10 shows a calculated film density (Calculated, black line) and a measured film density (Actual, red line), and FIG. 11 shows a difference between the two densities. A composition ratio of each of the material films according to Experimental Examples 1 to 8 was calculated from film densities of the InO thin film and the ZnO thin film reported in the document (InO=7.18 g/cm³, ZnO=5.61 g/cm³).

As shown in FIGS. 10 and 11, the largest difference was exhibited in the IZO material film according to Experimental Example 3 (CH—IZO). Accordingly, the IZO material film according to Experimental Example 3 (CH—IZO) was deposited with a high film density as compared with a homogeneous thin film due to the crystal phase.

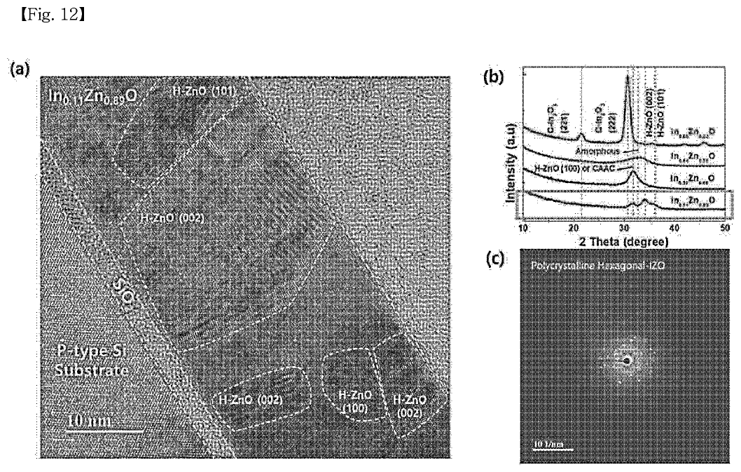

FIG. 12 is a view for specifically describing an IZO material film according to Experimental Example 2 of the present invention.

Referring to (a) of FIG. 12, a transmission electron microscope (TEM) image of the IZO material film according to Experimental Example 2 is shown. Referring to (b) of FIG. 12, an X-ray diffraction (XRD) result of the IZO material film according to Experimental Example 2 is shown. Referring to (c) of FIG. 12, a selected area electron diffraction (SAED) pattern analysis result of the IZO material film according to Experimental Example 2 is shown.

As shown in (a) of FIG. 12, the IZO material film according to Experimental Example 2 was polycrystalline, in which a plurality of grains were formed, and matched well with a hexagonal-ZnO crystal peak identified in (b) of FIG. 12. In addition, as shown in (c) of FIG. 12, when considering that a plurality of points were exhibited in the same spacing, grains of crystals in various directions were formed.

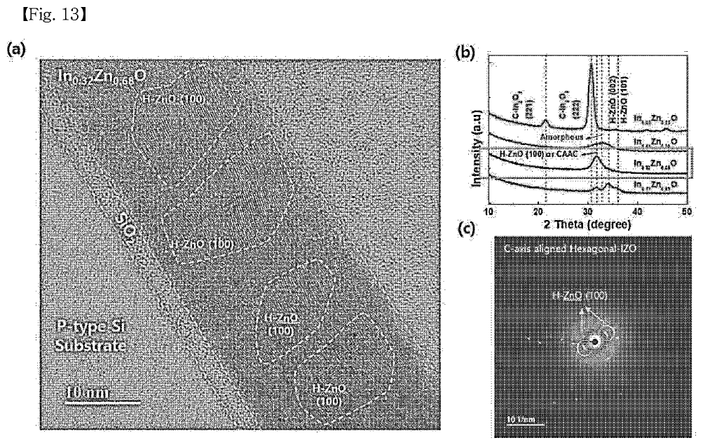

FIG. 13 is a view for specifically describing an IZO material film according to Experimental Example 3 of the present invention.

Referring to (a) of FIG. 13, a transmission electron microscope (TEM) image of the IZO material film according to Experimental Example 3 is shown. Referring to (b) of FIG. 13, an X-ray diffraction (XRD) result of the IZO material film according to Experimental Example 3 is shown. Referring to (c) of FIG. 13, a selected area electron diffraction (SAED) pattern analysis result of the IZO material film according to Experimental Example 3 is shown.

As shown in (a) of FIG. 13, the IZO material film according to Experimental Example 3 exhibited a C-axis orientation. As shown in (b) of FIG. 13, a single phase were not exhibited at the peak, formation of grain boundaries in various directions were not exhibited in (a) of FIG. 13, and a thin film subjected to a C-axis orientation, which is similar to a quasi-single crystal orientation, was deposited. As shown in (c) of FIG. 13, points aligned to one side were exhibited without exhibiting a plurality of points like a polycrystalline case, so that the result matched well with the TEM image and XRD data.

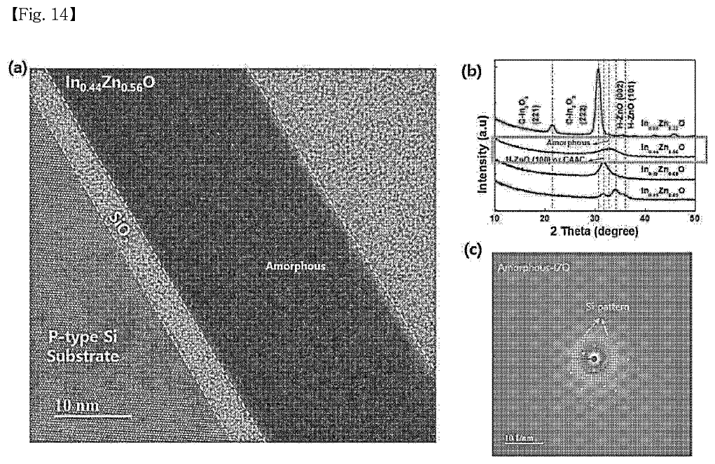

FIG. 14 is a view for specifically describing an IZO material film according to Experimental Example 4 of the present invention.

Referring to (a) of FIG. 14, a transmission electron microscope (TEM) image of the IZO material film according to Experimental Example 4 is shown. Referring to (b) of FIG. 14, an X-ray diffraction (XRD) result of the IZO material film according to Experimental Example 4 is shown. Referring to (c) of FIG. 14, a selected area electron diffraction (SAED) pattern analysis result of the IZO material film according to Experimental Example 4 is shown.

As shown in (a) to (c) of FIG. 14, the IZO material film according to Experimental Example 4 was an amorphous thin film.

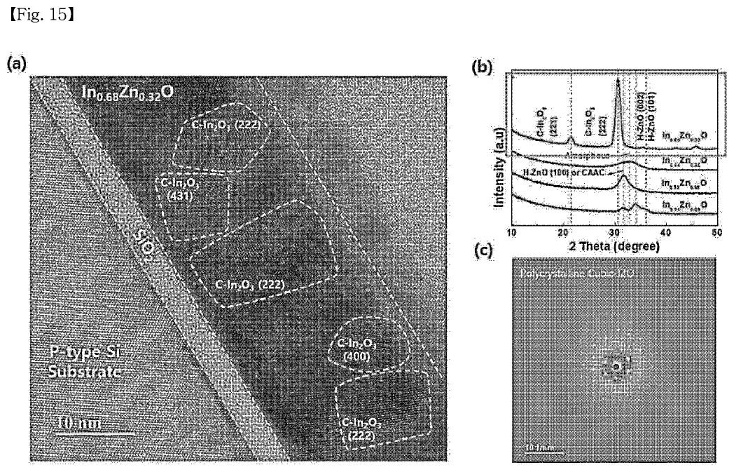

FIG. 15 is a view for specifically describing an IZO material film according to Experimental Example 8 of the present invention.

Referring to (a) of FIG. 15, a transmission electron microscope (TEM) image of the IZO material film according to Experimental Example 8 is shown. Referring to (b) of FIG. 15, an X-ray diffraction (XRD) result of the IZO material film according to Experimental Example 8 is shown. Referring to (c) of FIG. 15, a selected area electron diffraction (SAED) pattern analysis result of the IZO material film according to Experimental Example 8 is shown.

As shown in (a) of FIG. 15, the IZO material film according to Experimental Example 8 was polycrystalline, in which a plurality of grains were formed. As shown in (b) of FIG. 15, the IZO material film according to Experimental Example 8 had a polycrystalline orientation of a cubic-InOₓ structure. As shown in (c) of FIG. 15, when considering that the IZO material film according to Experimental Example 8 exhibited a plurality of points in the SAED pattern, various crystal orientations were grown in various directions.

The crystal phases of the IZO material films according to Experimental Examples 1 to 8 will be summarized in <Table 2> below.

TABLE 2

| Classification | Crystal phase |
|---|---|
| Experimental Example 1 | Hexagonal-ZnO-based polycrystalline |
| Experimental Example 2 | Hexagonal-ZnO-based polycrystalline |
| Experimental Example 3 | Hexagonal-ZnO-based C-axis oriented |
| Experimental Example 4 | Amorphous |
| Experimental Example 5 | Amorphous |
| Experimental Example 6 | Amorphous |
| Experimental Example 7 | Cubic-InOₓ-based polycrystalline |
| Experimental Example 8 | Cubic-InOₓ-based polycrystalline |

Manufacture of IZO Material Film according to Comparative Examples 1 to 5

An IZO material film was manufactured through a thermal ALD process. In detail, an indium precursor and a zinc precursor, which are identical to the precursors used in the processes of manufacturing the IZO material films according to the experimental examples described above, were used, and O₃ was used as a reactant.

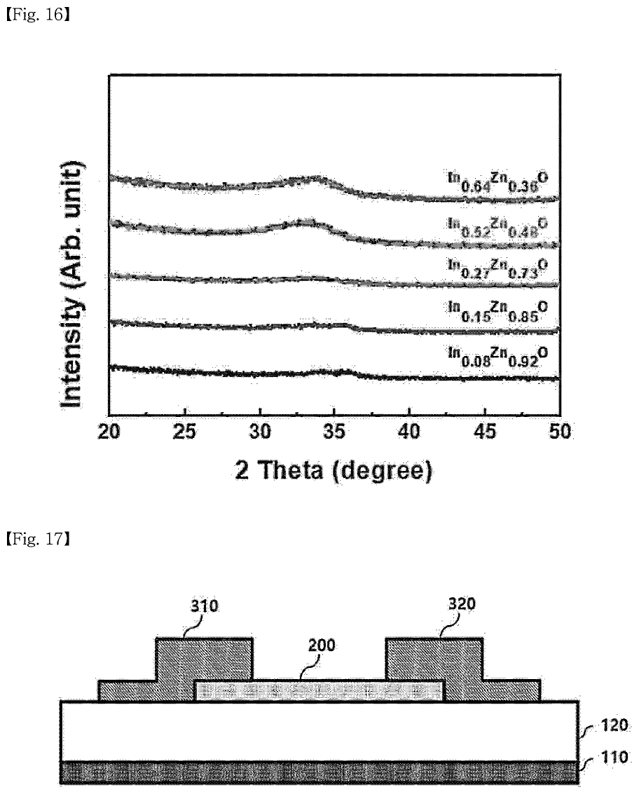

In_{0.08}Zn_{0.92}O was defined as an IZO material film according to Comparative Example 1, In_{0.15}Zn_{0.85}O was defined as an IZO material film according to Comparative Example 2, In_{0.27}Zn_{0.73}O was defined as an IZO material film according to Comparative Example 3, In_{0.52}Zn_{0.48}O was defined as an IZO material film according to Comparative Example 4, and In_{0.64}Zn_{0.36}O was defined as an IZO material film according to Comparative Example 5. FIG. 16 is a view for describing XRD analysis results of IZO material films according to comparative examples of the present invention.

Referring to FIG. 16, after the IZO material films according to Comparative Examples 1 to 5 are prepared, X-ray diffraction (XRD) analysis was performed on each of the IZO material films. As shown in FIG. 16, the IZO material film manufactured through thermal-ALD was formed as an amorphous thin film in all composition ranges. Accordingly, when compared to thermal-ALD, PEALD had highly reactive radicals to induce crystal growth, and exhibited control of a crystal phase in a specific region.

### Manufacture of Transistor According to Experimental Examples 1 to 8

A thin film transistor (TFT) including a P++Si gate, a thermal SiO₂ gate insulating film having a thickness of 100 nm, an IZO active film having a thickness of 10 nm, and ITO source and drain electrodes, each having a thickness of 100 nm, was manufactured. In more detail, each of the IZO material films according to Experimental Examples 1 to 8 was used as an active film, and TFTs using the IZO material films according to Experimental Examples 1 to 8 were defined as TFTs according to Experimental Examples 1 to 8.

FIG. 17 is a view for describing a transistor according to the experimental example of the present invention.

Referring to FIG. 17, a transistor according to the experimental example may be a TFT having a bottom gate structure. In more detail, the transistor according to the experimental example may include: a gate 110; a gate insulating film 120 disposed on the gate; an active film 200 disposed on the gate insulating film; and a source electrode 310 and a drain electrode 320 disposed on the gate insulating film, wherein one side of the source electrode 310 may make contact with one side of the active film 200, and one side of the drain electrode 310 may make contact with an opposite side of the active film 200.

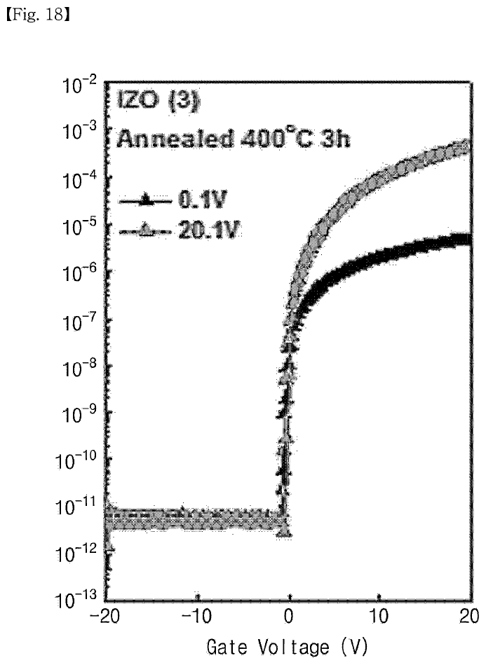

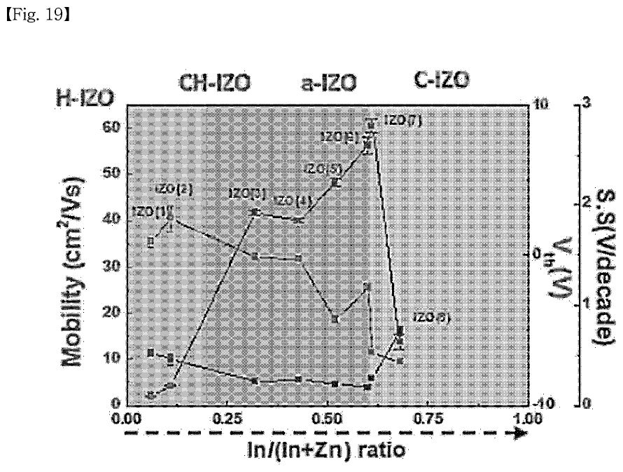

FIG. 18 is a view for describing electrical characteristics of a transistor according to Experimental Example 3 of the present invention, and FIG. 19 is a view for comparing electrical characteristics of transistors according to the experimental examples of the present invention.

As shown in FIGS. 18 and 19, mobility (cm²/Vs) was gradually increased as a composition ratio of In₂O₃ in the IZO material film increases (Experimental Example 1 to Experimental Example 6), whereas mobility (cm²/Vs) was significantly decreased as a phase changes to a cubic structure (Experimental Example 7 and Experimental Example 8).

As a result of comparing Vₜₕ (V), the IZO material films according to Experimental Examples 1 to 4 had Vₜₕ (V) values that are close to 0 V, whereas the IZO material films according to Experimental Examples 5 to 8 had negative values shifted from 0 V. In particular, the IZO material film according to Experimental Example 3 exhibited high mobility despite a low indium (In) content as compared with the IZO material film according to Experimental Example 4.

As a result, when an IZO material film is manufactured through the PEALD process, the IZO material film may be manufactured to have a C-axis crystal phase, so that electrical characteristics of a semiconductor device (e.g., a transistor) to which the IZO material film is applied may be improved. In detail, an IZO material film having a C-axis crystal phase may be manufactured by controlling the number of repetitions of the second unit process with respect to the number of repetitions of the first unit process to be greater than 6:1 and less than 1:3, and the IZO material film manufactured under this condition may have a composition of InₓZn_{y}O (x: greater than 0.11 and less than 0.44, y: greater than 0.56 and less than 0.89).

Although the exemplary embodiments of the present invention have been described in detail above, the scope of the present invention is not limited to a specific embodiment, and shall be interpreted by the appended claims. In addition, it is to be understood by a person having ordinary skill in the art that various changes and modifications can be made without departing from the scope of the present invention.

### INDUSTRIAL APPLICABILITY

An IZO material film according to an embodiment of the present disclosure may be utilized in various industrial fields such as semiconductor devices and display devices.

1. A method for manufacturing an IZO material film, the method comprising:
preparing a substrate;
forming a first material film including indium oxide on the substrate by reacting a first precursor including indium (In) with a first reactant including plasma; and
forming a second material film including zinc oxide on the first material film by reacting a second precursor including zinc (Zn) with a second reactant including plasma,
wherein each of the forming of the first material film and the forming of the second material film is repeatedly performed a plurality of times, and
a ratio of a number of repetitions of the forming of the second material film to a number of repetitions of the forming of the first material film is controlled to control crystal growth of an IZO material film in which the first material film and the second material film are stacked.

2. The method of claim 1, wherein the ratio of the number of repetitions of the forming of the second material film to the number of repetitions of the forming of the first material film is controlled to be greater than 6:1 and less than 1:3,
so that the IZO material film is subjected to C-axis oriented crystal growth.

3. The method of claim 1, wherein the ratio of the number of repetitions of the forming of the second material film to the number of repetitions of the forming of the first material film is controlled to be greater than or equal to 1:3 and less than or equal to 1:6,
so that the IZO material film is subjected to polycrystalline crystal growth.

4. The method of claim 1, wherein the ratio of the number of repetitions of the forming of the second material film to the number of repetitions of the forming of the first material film is controlled to be greater than or equal to 12:1 and less than or equal to 6:1,
so that the IZO material film is subjected to amorphous crystal growth.

5. The method of claim 1, wherein the ratio of the number of repetitions of the forming of the second material film to the number of repetitions of the forming of the first material film is controlled to be greater than or equal to 36:1 and less than or equal to 18:1,
so that the IZO material film is subjected to polycrystalline crystal growth.

6. The method of claim 1, wherein the first material film exhibits a cubic-InOₓ crystal phase (x>0) as a result of X-ray diffraction (XRD) analysis.

7. The method of claim 1, wherein the second material film exhibits a hexagonal-ZnO crystal phase as a result of X-ray diffraction (XRD) analysis.

8. The method of claim 1, wherein the first precursor is represented by <Chemical Formula 1>:

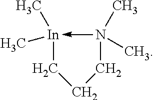

9. The method of claim 1, wherein the second precursor is represented by <Chemical Formula 2>:

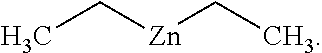

10. An IZO material film, wherein, in an InₓZn_{y}O material film (x,y>0) in which a first material film including indium oxide and a second material film including zinc oxide are stacked,
a composition of indium (In) and zinc (Zn) in the InₓZn_{y}O material film (x,y>0) is controlled to control a crystal phase of the InₓZn_{y}O material film (x,y>0).

11. The IZO material film of claim 10, wherein x is controlled to be greater than 0.11 and less than 0.44, and y is controlled to be greater than 0.56 and less than 0.89, so that the InₓZn_{y}O material film has a C-axis crystal phase.

12. The IZO material film of claim 10, wherein x is controlled to be greater than or equal to 0.07 and less than or equal to 0.11, and y is controlled to be greater than or equal to 0.89 and less than or equal to 0.93, so that the InₓZn_{y}O material film has a hexagonal-ZnO crystal phase.

13. The IZO material film of claim 10, wherein x is controlled to be greater than or equal to 0.44 and less than or equal to 0.60, and y is controlled to be greater than or equal to 0.40 and less than or equal to 0.56, so that the InₓZn_{y}O material film has an amorphous crystal phase.

14. The IZO material film of claim 10, wherein x is controlled to be greater than or equal to 0.62 and less than or equal to 0.68, and y is controlled to be greater than or equal to 0.32 and less than or equal to 0.38, so that the InₓZn_{y}O material film has a cubic-InO crystal phase.
